(19) United States
(12) Patent Application Publication
(10) Pub. No.: US 2023/0343765 A1
(43) Pub. Date: Oct. 26, 2023

(54) Dual Side Intelligent Power Device Integration

(71) Applicant: Taiwan Semiconductor Manufacturing Co., Ltd., Hsinchu (TW)

(72) Inventors: Shin-Puu Jeng, Hsinchu (TW); Hsien-Wei Chen, Hsinchu (TW); Meng-Liang Lin, Hsinchu (TW); Ying-Ju Chen, Tuku Township (TW); Shuo-Mao Chen, New Taipei City (TW)

(21) Appl. No.: 17/804,928

(22) Filed: Jun. 1, 2022

Related U.S. Application Data
(60) Provisional application No. 63/363,590, filed on Apr. 26, 2022.

(51) Int. Cl. H01L 25/10; H01L 25/00; H01L 23/538; H01L 23/00; H01L 21/48

(52) U.S. Cl. CPC H01L 25/105; H01L 25/50; H01L 23/5385; H01L 24/17; H01L 21/4857; H01L 25/18

(57) ABSTRACT

A method includes forming a first package component, which includes an interposer, and a first die bonded to a first side of the interposer. A second die is bonded to a second side of the interposer. The second die includes a substrate, and a through-via penetrating through the substrate. The method further includes bonding a second package component to the first package component through a first plurality of solder regions. The first package component is further electrically connected to the second package component through the through-via in the second die. The second die is further bonded to the second package component through a second plurality of solder regions.

### PRIORITY CLAIM AND CROSS-REFERENCE

This application claims the benefit of the following provisionally filed U.S. Patent application: Application No. 63/363,590, filed on Apr. 26, 2022, and entitled “Dual Side Intelligent Power Device Integration,” which application is hereby incorporated herein by reference.

### BACKGROUND

Intelligent Power Devices (IPDs) are often used in integrated circuit systems. IPDs may be bonded to interposers, and are located between the interposers and the corresponding package substrates.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 illustrate the cross-sectional views of intermediate stages in the formation of a package in accordance with some embodiments.

FIGS. 12-17 illustrate the cross-sectional views of some packages adopting the Intelligent Power Devices (IPDs) in accordance with some embodiments.

FIG. 18 illustrates a top view of a package adopting IPDs in accordance with some embodiments.

FIG. 19 illustrates a magnified view of a portion of a package adopting an IPD in accordance with some embodiments.

FIG. 20 illustrates an example IPD in accordance with some embodiments.

FIG. 21 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, the package includes an Intelligent Power Device (IPD) between a first package component and a second package component. The first package component and the second package component are bonded with each other. The first and the package components may be interposers, package substrate, etc. The IPD may include a semiconductor substrate, and through-vias penetrating through the semiconductor substrate. The IPD electrically interconnects the first and the second package components through through-vias. Accordingly, electrical signal may also pass through the IPD, and the chip area occupied by the IPD may be used for the electrical connection between the first and the second package components. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

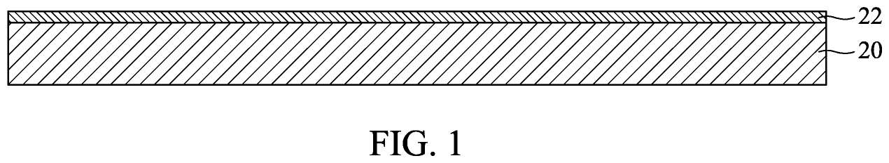

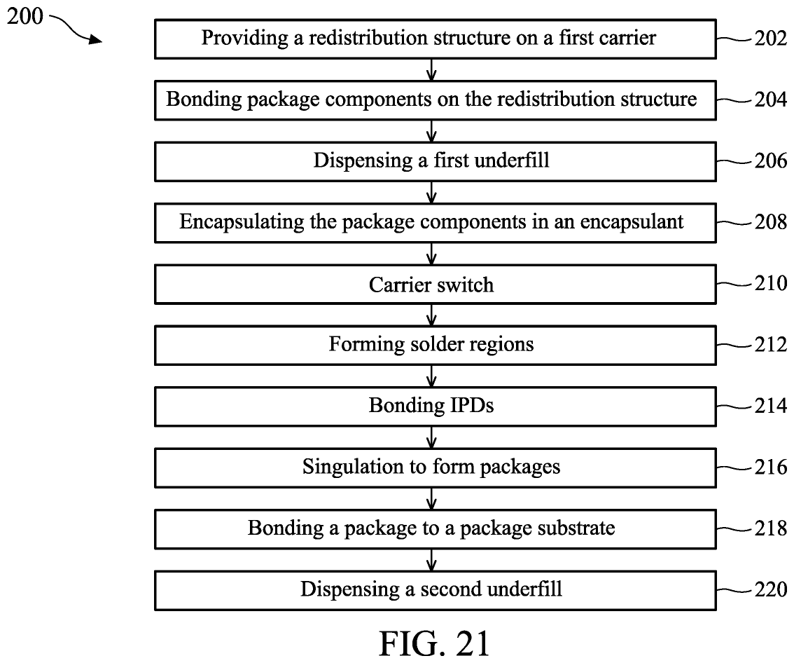

FIGS. 1 through 11 illustrate the cross-sectional views of intermediate stages in the formation of a package in accordance with some embodiments of the present disclosure. The corresponding processes are also reflected schematically in the process flow shown in FIG. 21.

FIG. 1 illustrates carrier 20, and release film 22 on carrier 20. Carrier 20 may be a glass carrier, a silicon wafer, an organic carrier, or the like. Carrier 20 may have a round top-view shape in accordance with some embodiments. Release film 22 may be formed of a polymer-based material and/or an epoxy-based thermal-release material (such as a Light-To-Heat-Conversion (LTHC) material), which is capable of being decomposed under radiation such as a laser beam, so that carrier 20 may be de-bonded from the overlying structures that will be formed in subsequent processes. In accordance with some embodiments of the present disclosure, release film 22 is applied on carrier 20 through coating.

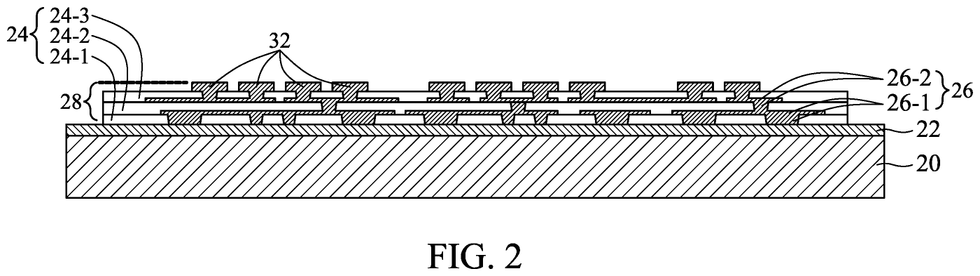

Referring to FIG. 2, a redistribution structure 28, which includes a plurality of dielectric layers 24 and a plurality of RDLs 26, is provided over the release film 22. The respective process is illustrated as process 202 in the process flow 200 as shown in FIG. 21. Redistribution structure 28 is alternatively referred to as an interposer 28. In accordance with some embodiments, interposer 28 is pre-formed, and the pre-formed interposer 28 is placed on release film 22. Interposer 28 may be an organic interposer comprising organic dielectric layers and redistribution lines. Alternatively, interposer 28 may include a semiconductor substrate, through-vias in the semiconductor substrate, and metal lines and vias on the opposite sides of, and electrically interconnected through, the through-vias.

In accordance with alternative embodiments, interposer 28 is formed layer-by-layer starting from release film 22. In the formation of interposer 28, a first dielectric layer 24-1 is first formed on release film 22, and is then patterned to form openings. In accordance with some embodiments of the present disclosure, dielectric layer 24-1 is formed of or comprises an organic material, which may be a polymer. The organic material may also be a photo-sensitive material. For example, dielectric layer 24-1 may be formed of or comprises polyimide, polybenzoxazole (PBO), benzocyclobutene (BCB), or the like.

Further referring to FIG. 2, a first plurality of Redistribution Lines (RDLs) 26 (denoted as 26-1) are formed on dielectric layer 24-1. In accordance with some embodiments, the formation of RDLs 26-1 may include forming a metal seed layer (not shown), which includes some portions over dielectric layer 24-1, and some other portions extending into dielectric layer 24-1. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, leaving RDLs 26-1 as shown in FIG. 2. The plated material may include copper, aluminum, cobalt, nickel, gold, silver, tungsten, or alloys thereof. In accordance with some embodiments of the present disclosure, the metal seed layer includes a titanium layer and a copper layer over the titanium layer. The metal seed layer may be formed using, for example, Physical Vapor Deposition (PVD) or a like process. The plating may be performed using, for example, an electrochemical plating process.

FIG. 2 further illustrates the formation of additional dielectric layers 24-2 and 24-3, and additional RDLs 26-2, for example. Throughout the description, dielectric layers 24-1, 24-2, and 24-3 are individually and collectively referred to as dielectric layers 24, and RDLs 26-1 and 26-2 are individually and collectively referred to as RDLs 26. In accordance with some embodiments, dielectric layer 24-2 is first formed on RDLs 26-1. The bottom surface of dielectric layer 24-2 is in contact with the top surfaces of RDLs 26-1 and dielectric layer 24-1. Dielectric layer 24-2 may be formed of or comprise an organic dielectric material, which may be a polymer. For example, dielectric layer 24-2 may comprise a photo-sensitive material such as PBO, polyimide, BCB, or the like. Dielectric layer 24-2 is then patterned to form via openings (occupied by the via portions of RDLs 26-2) therein. Hence, some pad portions of RDLs 26-1 are exposed through the openings in dielectric layer 24-2.

Next, RDLs 26-2 are formed on dielectric layer 24-2 to connect to RDLs 26-1. RDLs 26-2 include via portions extending into the openings in dielectric layer 24-2, and trace portions (metal line portions) over dielectric layer 24-2. RDLs 26-2 may be formed of or comprise a material selected from the same group of candidate materials for forming RDLs 26-1, and may include copper, aluminum, cobalt, nickel, gold, silver, tungsten, or the like. In accordance with some embodiments, the formation of RDLs 26-2 may include depositing a blanket metal seed layer extending into the via openings, and forming and patterning a plating mask (such as a photoresist), with openings formed in the plating mask and directly over the via openings. A plating process is then performed to plate a metallic material, which fully fills the via openings, and has some portions higher than the top surface of dielectric layer 24-2. The plating mask is then removed, followed by an etching process to remove the exposed portions of the metal seed layer, which was previously covered by the plating mask. The remaining portions of the metal seed layer and the plated metallic material are RDLs 26-2. RDLs 26-2 include RDL lines (also referred to as traces or trace portions) and via portions (also referred to as vias). The trace portions are over dielectric layer 24-2, and the via portions are in dielectric layer 24-2. Each of the vias may have a tapered profile, with the upper portions wider than the corresponding lower portions.

The metal seed layer and the plated material may be formed of the same material or different materials. For example, the metal seed layer may include a titanium layer, and a copper layer over the titanium layer. The plated metallic material in RDLs 26-2 may include a metal or a metal alloy including copper, aluminum, tungsten, or the like, or alloys thereof.

After the formation of RDLs 26-2, there may be more dielectric layers and the corresponding RDLs formed, with the upper RDLs over and landing on the respective lower RDLs. For example, FIG. 2 illustrates dielectric layer 24-3. It is appreciated that there may be more or fewer dielectric layers and RDLs than illustrated. The materials of dielectric layer 24-3 may be selected from the same group (or different group) of candidate materials as dielectric layers 24-1 and 24-2. For example, dielectric layer 24-3 may be formed of an organic material, which may be a polymer such as polyimide, PBO, BCB, or the like.

After the formation of a top dielectric layer such as dielectric layer 24-3, electrical connectors 32 may be formed. Electrical connectors 32 may be formed of or comprise micro-bumps, metal pads, metal pillars, Under-Bump-Metallurgies (UBMs), solder regions, and/or the like. The formation of electrical connectors 32 may also be similar to the formation of RDLs 26-2, which formation process includes patterning the top dielectric layer to expose the underlying RDLs, forming a metal seed layer, forming a patterned plating mask, performing one or a plurality of plating processes to form metal pillars 32, removing the plating mask, and etching the metal seed layer. Electrical connectors 32 may also include copper, aluminum, cobalt, nickel, gold, silver, tungsten, alloys thereof, and/or multi-layers thereof. When electrical connectors 32 include solder regions, the solder regions may be plated using the same plating mask used for plating the underlying non-solder portions, followed by a reflow process to round the surfaces of the solder regions. The solder regions may include Sn and Ag, and may or may not include gold.

In accordance with alternative embodiments, the dielectric materials in interposer 28 may comprise a ceramic material, a resin (e.g. epoxy-based resin, polyimide-based resin), prepreg, glass, or the like. Throughout the description, dielectric layers 24, RDLs 26, and electrical connectors 32 collectively form interposer 28, which is alternatively referred to as interconnect component 28 or organic interposer 28.

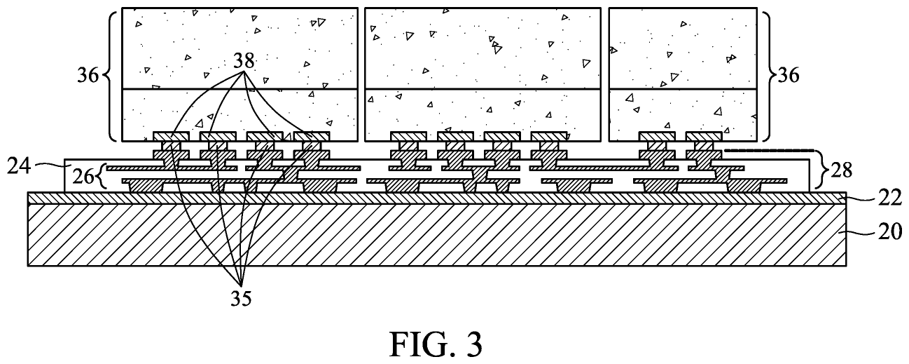

FIG. 3 illustrates the bonding of package components 36 to interconnect component 28. The respective process is illustrated as process 204 in the process flow 200 as shown in FIG. 21. Electrical connectors 38, which are the surface features of package components 36, may be bonded to electrical connectors 32 through solder regions 35 in accordance with some embodiments. Electrical connectors 38 may be UBMs, metal pillars, bond pads, or the like. In accordance with alternative embodiments, electrical connectors 38 are metal pillars, and are bonded to electrical connectors 32 through direct metal-to-metal bonding, with no solder regions therebetween.

In accordance with some embodiments, package components 36 include a plurality of groups of package components, with the groups being identical to each other. Each of the groups may be a single-component group or a multi-component group. For example, FIG. 3 illustrates an example in which each group includes three package components 36. In accordance with some embodiments, package components 36 include a logic die, which may be a Central Processing Unit (CPU) die, a Graphic Processing Unit (GPU) die, a mobile application die, a Micro Control Unit (MCU) die, an input-output (IO) die, a BaseBand (BB) die, an Application processor (AP) die, or the like. Package components 36 may also include memory dies such as Dynamic Random-Access Memory (DRAM) dies, Static Random-Access Memory (SRAM) dies, or the like. The memory dies may be discrete memory dies, or may be in the form of a die stack that includes a plurality of stacked memory dies. Package components 36 may also include System-on-Chip (SOC) dies. Package components 36 may be discrete device dies or packages.

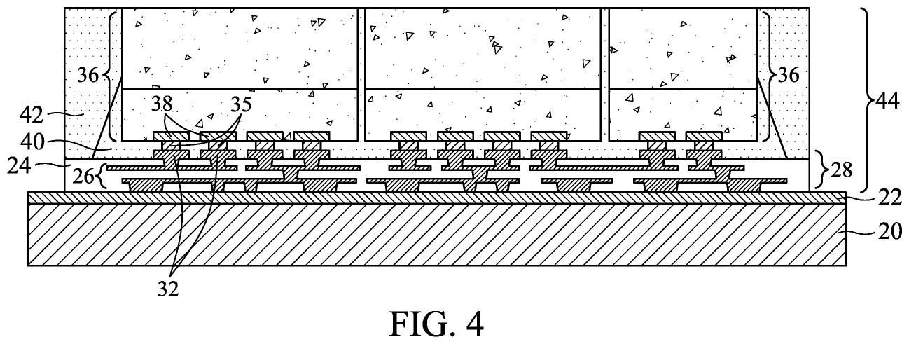

Referring to FIG. 4, underfill 40 is dispensed into the gaps between package components 36 and interposer 28. The respective process is illustrated as process 206 in the process flow 200 as shown in FIG. 21. Underfill 40 may also be dispensed between neighboring package components 36 that are in the same group of package components. In accordance with some embodiments, underfill 40 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like. The filler particles may have spherical shapes. Underfill 40 is dispensed in a flowable form, and is then cured. In accordance with alternative embodiments, underfill 40 is formed of a non-conductive film, which is placed on interposer 28 first, and package components 36 are pressed against interposer 28, so that the electrical connectors in package components 36 penetrate through the non-conductive film to contact electrical connectors 32.

Next, package components 36 are encapsulated in encapsulant 42. The respective process is illustrated as process 208 in the process flow 200 as shown in FIG. 21. Encapsulant 42 may be a molding compound, a molding underfill, an epoxy, and/or a resin. Encapsulant 42 may include a base material, and a filler in the base material. The base material may include a polymer material, which may be or may comprise a plastic, an epoxy resin (such as Epoxy Cresol Novolac (ECN), biphenyl epoxy resin, or a multifunctional liquid epoxy resin), polyimide, polyethylene terephthalate (PET), polyvinyl chloride (PVC), polymethylmethacrylate (PMMA), or the like. The filler may include titanium dioxide, carbon black, calcium carbonate, silica, fiber, clay, ceramic, inorganic particles, and or the like, and may be in the form of filler particles.

A planarization process such as a Chemical Mechanical Polish (CMP) process or a mechanical grinding process is then performed to polish encapsulant 42. Package components 36 may be exposed as a result of the planarization process. For example, when package components 36 comprise semiconductor substrates, the semiconductor substrates may be exposed. Throughout the description, the features over release film 22, which features include interposer 28, package components 36, underfill 40, and encapsulant 42, are collectively referred to as reconstructed wafer 44.

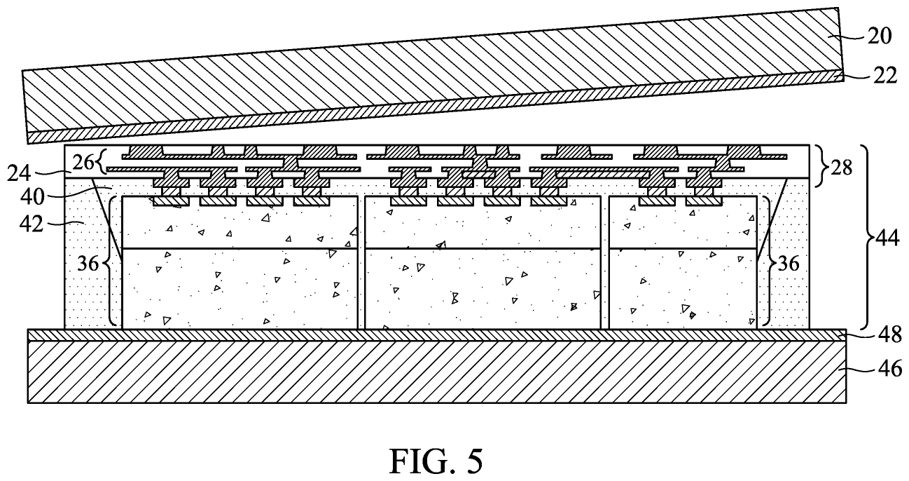

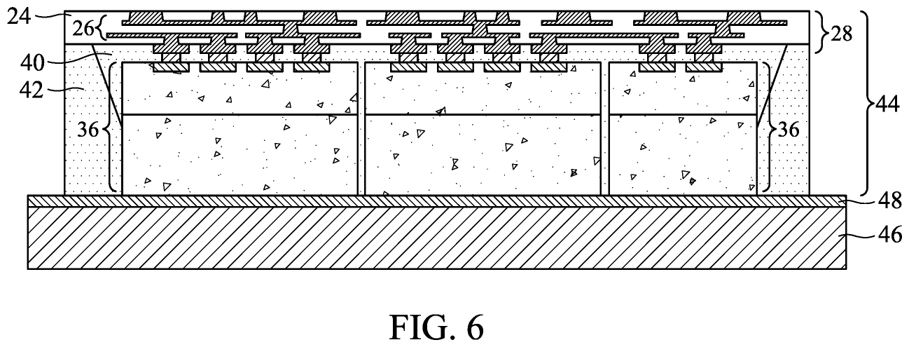

FIG. 5 illustrates a carrier switch process. The respective process is illustrated as process 210 in the process flow 200 as shown in FIG. 21. First, carrier 46 is adhered to an opposite side of the reconstructed wafer 44 than carrier 20. Release film 48, which may also comprise a thermal release film such as an LTHC, is used to adhere carrier 46 to reconstructed wafer 44. The reconstructed wafer 44 is then de-bonded from carrier 20, for example, by projecting UV light or a laser beam, which penetrates through carrier 20, on release film 22. Release film 22 decomposes under the heat of the UV light or the laser beam. The reconstructed wafer 44 may then be de-bonded from carrier 20. The resulting reconstructed wafer 44 is illustrated in FIG. 6.

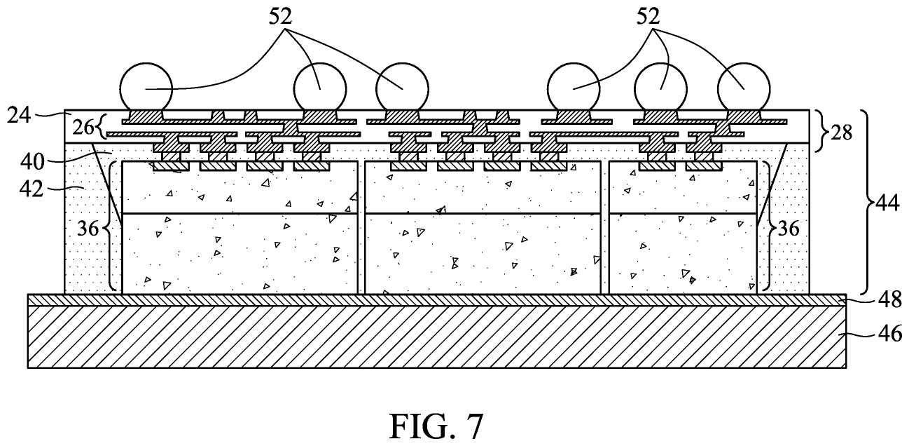

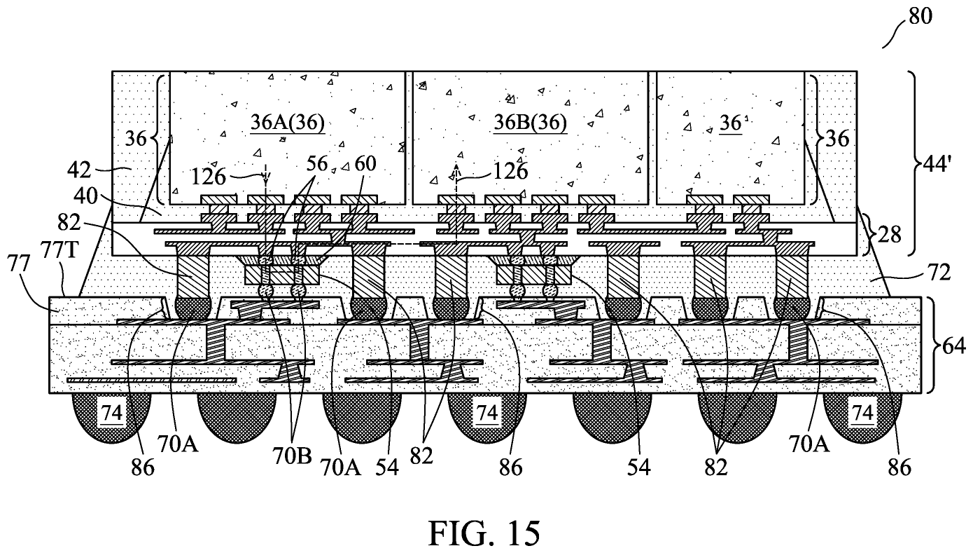

FIG. 7 illustrates the formation of solder regions 52. The respective process is illustrated as process 212 in the process flow 200 as shown in FIG. 21. In accordance with some embodiments, the formation process includes placing solder balls on RDLs 26-1, and performing a reflow process. In accordance with alternative embodiments as shown in FIG. 15, both of metal posts 82 and solder regions are formed. The formation process may also include depositing a metal seed layer, forming a patterned plating mask, and plating solder regions 52 on the metal posts. The plating mask is then removed, followed by the etching of the metal seed layer. A reflow process is then performed to reflow the solder regions 52.

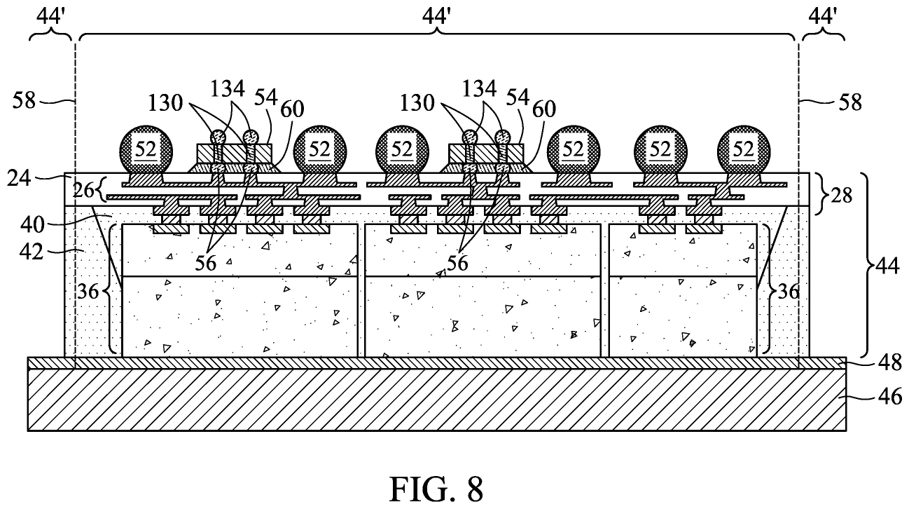

FIG. 8 illustrates the bonding of dies 54 to interposer 28 through solder regions 56. The respective process is illustrated as process 214 in the process flow 200 as shown in FIG. 21. Next, underfill 60 is dispensed into the gaps between dies 54 and interposer 28. Dies 54 may include Intelligent Power Devices (referred to as IPDs), which may include high-performance semiconductor power switches with built-in protection circuits capable of absorbing energy such as inductive loads. In accordance with alternative embodiments, dies 54 may include an independent passive device (also referred to as an IPD) such capacitor(s), a resistor(s), a transmitter(s) therein. Dies 54 may also be bridge dies. In the subsequent discussion, dies 54 are referred to as IPDs 54, while they may also be of another type such as bridge dies.

In accordance with some embodiments, IPD 54 comprise pre-formed solder regions 134 at its top surface. In accordance with alternative embodiments, IPD 54 do not include pre-formed solder regions at its top surface. Accordingly, the solder regions 134 are shown as being dashed to indicate that solder regions 134 may be, or may not be, formed.

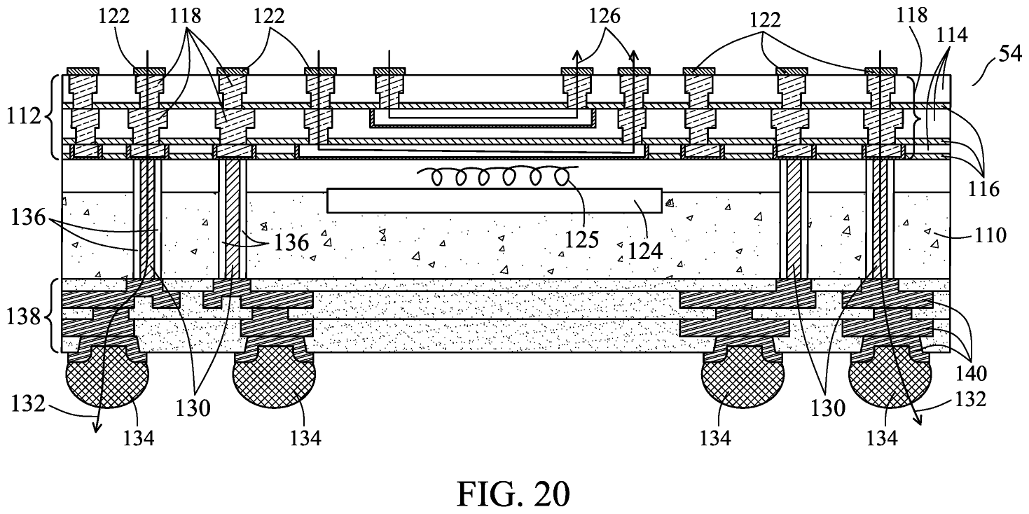

FIG. 20 illustrates the cross-sectional view of an example IPD 54. In accordance with some embodiments of the present disclosure, IPD 54 includes substrate 110. substrate 110 may be a semiconductor substrate such as a silicon substrate. In accordance with alternative embodiments (form example, when IPD 54 includes a bride die), the substrate 110 of IPD 54 may be an organic substrate, a glass substrate, a laminate substrate, or the like. Interconnect structure 112 is formed over substrate 110, and includes dielectric layers 114, etch stop layers 116, and metal lines and vias 118 in dielectric layers 114.

Dielectric layers 114 may include IMD layers. In accordance with some embodiments of the present disclosure, some lower ones of dielectric layers 114 are formed of low-k dielectric materials having dielectric constants (k-values) lower than 3.8, and the k values may be lower than about 3.0. Dielectric layers 114 may be formed of a carbon-containing low-k dielectric material, Hydrogen SilsesQuioxane (HSQ), MethylSilsesQuioxane (MSQ), or the like. Metal lines and vias 118 may be fine conductive features with small pitches, which may be smaller than about 1 μm, so that the density of the metal lines and vias 118 may be increased. The formation processes may include single damascene and dual damascene processes.

Dielectric layers 114 may further include a passivation layer(s) over the dielectric layers 114 that have low k values. The passivation layer has the function of isolating the underlying low-k dielectric layers (if any) from the adverse effect of detrimental chemicals and moisture. The passivation layer may be formed of or comprise non-low-k dielectric materials such as silicon oxide, silicon nitride, USG, or the like, or composite layers thereof. Bond pads 122 are formed at the surface of IPD 54.

In accordance with some embodiments, IPD 54 includes intelligent power devices 124, which may include a high-performance semiconductor power switch with built-in protection circuits capable of absorbing energy such as inductive loads. For example, intelligent power devices 124 may include transistors, fuses, relays, and/or the like. In accordance with alternative embodiments, IPD 54 includes a passive device(s) 125, which is schematically illustrated. Passive devices 125 may include a capacitor, a resistor, an inductor, and/or the like.

In accordance with yet alternative embodiments, IPD 54 may be a bridge die, which is used for electrically and signally interconnecting package components 36 (FIGS. 8). Metal lines and vias 118 and bond pads 122 may collectively form a plurality of conductive paths (bridges) 126, each including two of the bond pads 122 and the corresponding metal lines/pads and vias 84.

In accordance with some embodiments of the present disclosure, IPD 54 further includes through-vias 130, backside interconnect structure 138 (including RDLs 140), and electrical connectors 134, which collectively form parts of conductive paths 132. Conductive paths 132 may further includes metal lines and vias 118 and metal pads 122. Isolation layers 136, which are formed of a dielectric material such as silicon oxide, silicon nitride, or the like, electrically isolate through-vias 130 from semiconductor substrate 110. Through-vias 130 may be formed of or comprise Cu, Al, W, or the like, or alloys thereof. IPD 54 thus is a dual-sided device, which has conductive features on both of the top side and the bottom side, which conductive features are electrically interconnected through through-vias 130.

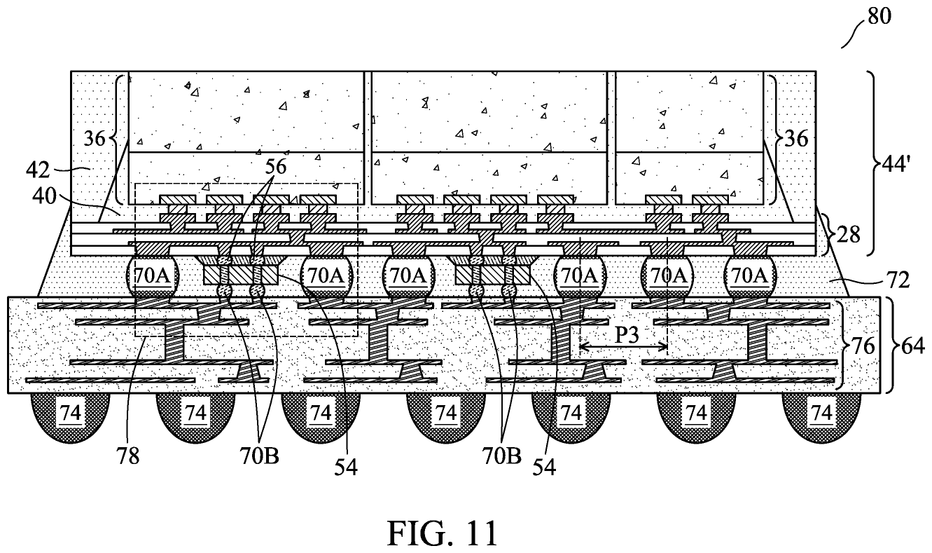

In accordance with some embodiments, some of conductive paths 132 are used for the through-connections that penetrate through IPD 54, and are not used for the interconnection within IPD 54. The corresponding conductive paths 132 thus are not connected to devices 124 and 125 (when formed) in IPD 54. Alternatively stated, each of these conductive paths 132 is a single-route conductive path that has no additional branch. In accordance with alternative embodiments, some of conductive paths 132 are electrically connected to passive devices 125 and/or intelligent power device 124 (when these devices are formed). Accordingly, through-vias 130 may also have the function of electrically connecting passive devices 125 and/or intelligent power device 124 to electrical connectors 134 and metal pads 122, and to package component 36 (FIG. 11) and/or package component 64 (FIG. 11).

Referring back to FIG. 8, in a subsequent process, reconstructed wafer 44 is de-bonded from carrier 46, for example, by projecting UV light or a laser beam on release film 48 through carrier 46. Release film 48 decomposes under the heat of the UV light or the laser beam. The reconstructed wafer 44 may then be separated from carrier 46. Reconstructed wafer 44 may then be placed on a dicing tape (not shown), which is attached and fixed on a frame (not shown). The reconstructed wafer 44 is then sawed in a singulation process along scribe lines 58, so that packages 44′, which are identical to each other, are separated from each other. The respective process is illustrated as process 216 in the process flow 200 as shown in FIG. 21.

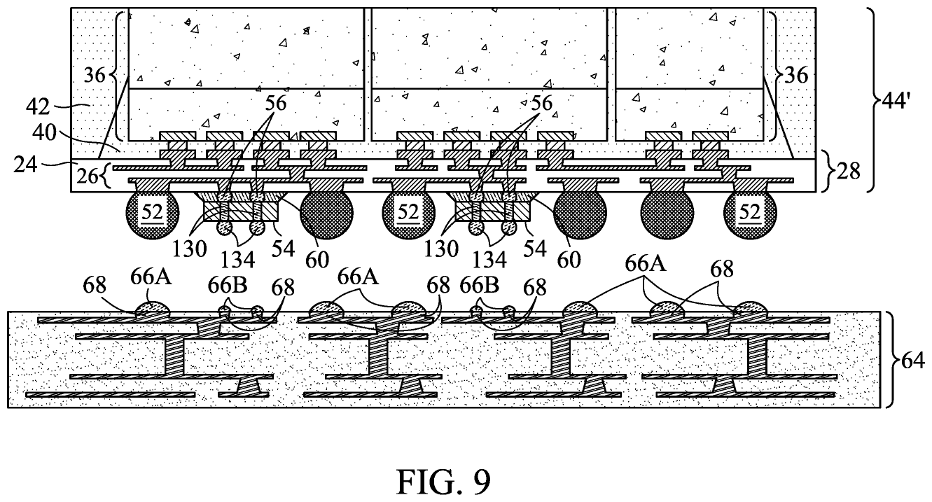

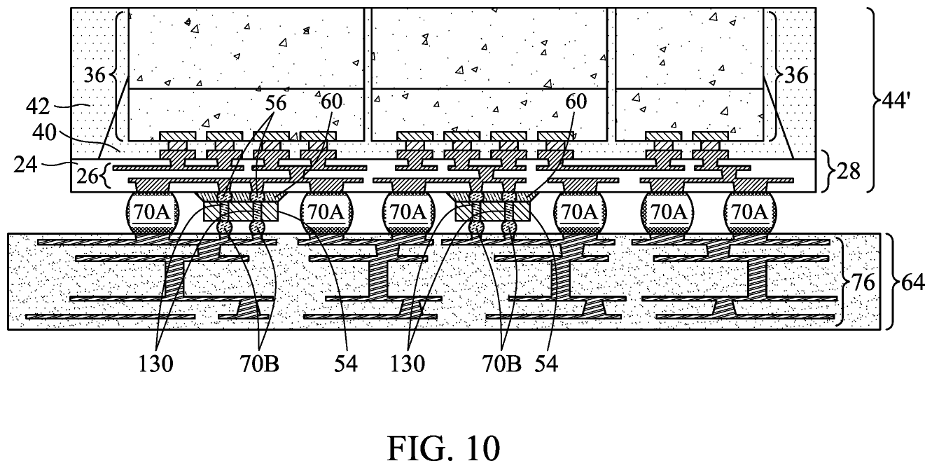

FIGS. 9 and 10 illustrate the alignment and the bonding of package 44′ on package component 64. Referring to FIG. 9, package 44′ is aligned to package component 64. In accordance with some embodiments, package component 64 may be or may comprise a package substrate (cored or core-less), an interposer, a package including device dies therein, a device die, a printed circuit board, or the like. Solder regions 66A and/or 66B may be, or may not be, pre-formed on the electrical connectors 68 of package component 64. In accordance with some embodiments, solder regions 66A are larger than solder regions 66B.

Next, package 44′ is placed on package component 64. A reflow process is then performed, so that package 44′ is bonded to package component 64, as shown in FIG. 10. The respective process is illustrated as process 218 in the process flow 200 as shown in FIG. 21. solder regions 70A are formed to bond interposer 28 to package component 64, and solder regions 70B are formed to bond IPDs 54 to package component 64. Solder regions 70A may include the solder regions 52 and 66A as shown in FIG. 9, and solder regions 70B may include the solder regions 134 and 66B as shown in FIG. 9.

Referring to FIG. 11, underfill 72 is dispensed into the gap between package 44′ and package component 64. Accordingly, underfill 72 also encapsulates IPD 54 therein. The respective process is illustrated as process 220 in the process flow 200 as shown in FIG. 21. Underfill 72 may be in contact with and encapsulates both of solder regions 70A and 70B.

FIG. 11 further illustrates the formation of electrical connectors 74, which are electrically connected to the RDLs 76 in package component 64. Package 80 is thus formed. In accordance with some embodiments, the formation of electrical connectors 74 includes etching a bottom dielectric layer in package component 64 to reveal the metal pads in RDLs 76, and forming electrical connectors 74 connecting to the metal pads. In accordance with some embodiments, electrical connectors 74 include solder regions, which may be formed by placing solder balls on the metal pads, and then performing a reflow process.

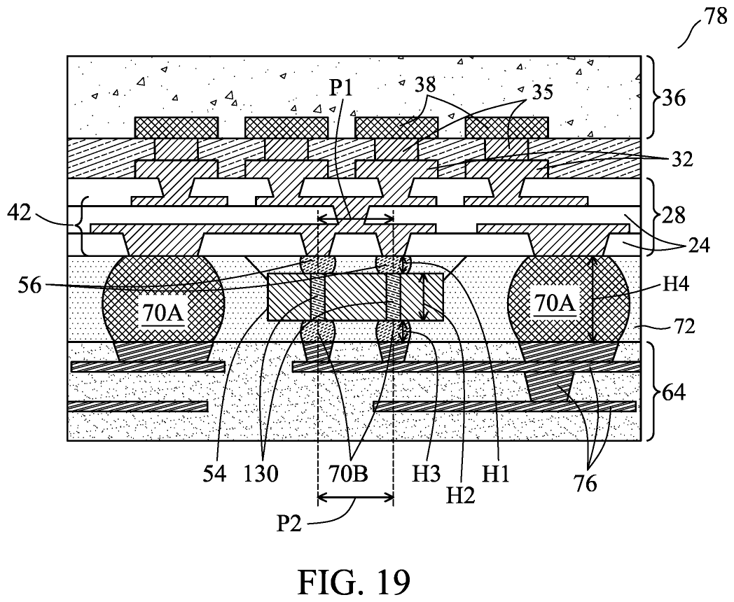

FIG. 19 illustrates a magnified view of region 78 in FIG. 11. In accordance with some embodiments. The heights H1, H2, H3, and H4 of solder regions 52, IPD 54, solder regions 70B, and solder regions 70A are selected for the reliability of the resulting package. For example, if any of solder regions 52, solder regions 70B, and solder regions 70A does not have enough height, they may be collapsed, causing bridging. Conversely, if any of solder regions 52, solder regions 70B, and solder regions 70A is provided with more than enough space, they may be over-stretched, and may not be able to reach and join the features they intend to join. In accordance with some embodiments, the height H1 of solder regions 52 and the height H3 of solder regions 70B may be in the range between about 5 μm and about 50 μm. Also, heights H1 and H3 may be selected to be similar to each other, for example, with ratio H1/H3 being in the range between about 0.7 and about 1.3. If one of heights H1 or H3 is too big, the corresponding solder regions 56 and 70B either need to be design too large, they may be over-stretched. Height H4 of solder regions 70A may be in the range between about 50 μm and about 200 μm.

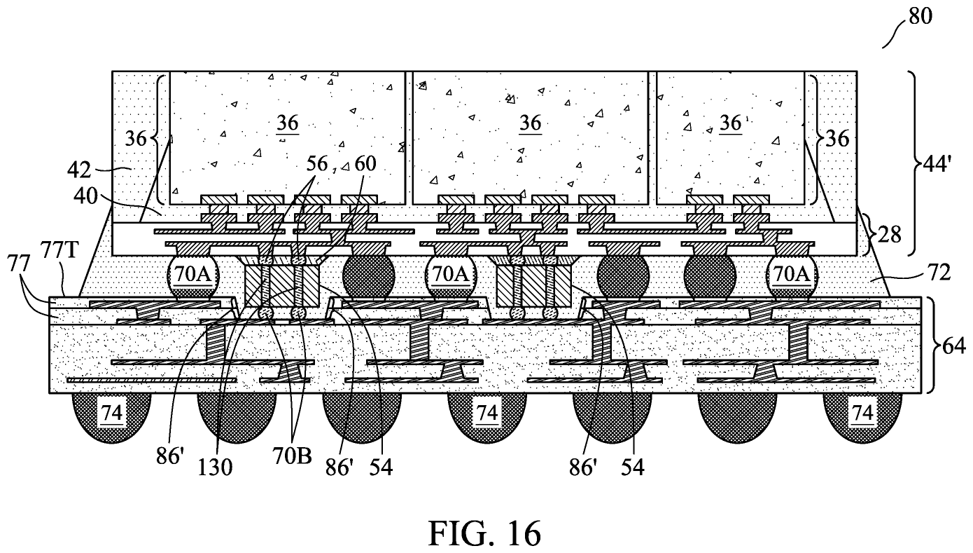

The actual values of heights H1 and H3 are also related to height H2 of IPD die 54, and the greater the height H2 is, the smaller heights H1 and H3 will be, and vice versa, assuming height H4 has been set. Furthermore, heights H1, H2, H3, and H4 may satisfy the relationship 0.8≤(H1+H2+H3)/H4≤1.2. If heights H1, H2, H3, and H4 satisfy this relationship, and if value (H1+H2+H3)) is not equal to H4, solution may be adopted, and either cavities may be formed in package component 64, or metal posts may be formed, as will be discussed referring to FIGS. 15 and 16. On the other hand, if ratio (H1+H2+H3)/H4 is too small or too big, for example, smaller than about 0.8 or greater than about 1.2, it will be difficult to overcome the discrepancy in values, even if the solution in FIG. 15 or FIG. 16 is adopted.

Solder regions 56 have pitch P1, and solder regions 70B have pitch P2. Due to process reasons, pitch P1 may be selected to be smaller than or equal to pitch P2. Since package component 64 (such as a package substrate) may not have too-small pitches P2 due to process reasons, the ratio P1/P2 cannot be significantly greater than 1. In accordance with some embodiments, the ratio P1/P2 may be in the range between about 0.5 and about 1. In accordance with some embodiments, pitch P3 (FIG. 11) of neighboring solder regions 70A may be greater than about 100 μm.

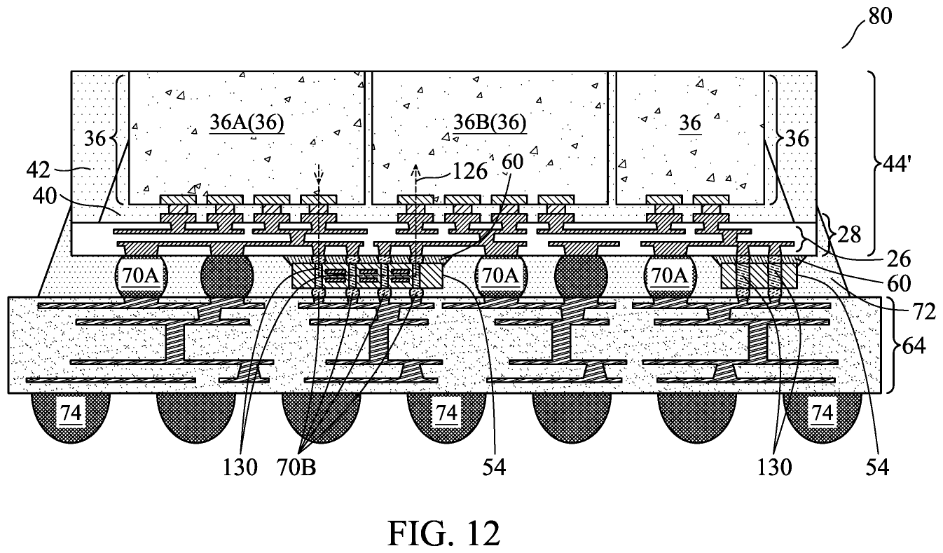

FIGS. 12 through 17 illustrate the packages 80 incorporating IPD 54 in accordance with alternative embodiments of the present disclosure. Unless specified otherwise, the materials and the formation processes of the components in these embodiments are essentially the same as the like components denoted by like reference numerals in the preceding embodiments shown in FIGS. 1 through 11. The details regarding the formation process and the materials of the components shown in FIGS. 12 through 17 may thus be found in the discussion of the preceding embodiments. In each of FIGS. 12 through 17, IPD device(s) 54 include through-vias 130 for interconnecting interposer 28 and package component 64. Furthermore, unless specified otherwise, each of IPD devices 54 may include one or more of the passive devices, intelligent power devices, and bridges in any combination.

FIG. 12 illustrates package 80, in which IPD 54 is also a bridge die in addition to its other functions, as aforementioned, such as including intelligent power devices and/or passive devices. In accordance with some embodiments of the present disclosure, bridges 126 (also refer to FIG. 20) electrically and signally interconnect two neighboring package components 36A and 36B.

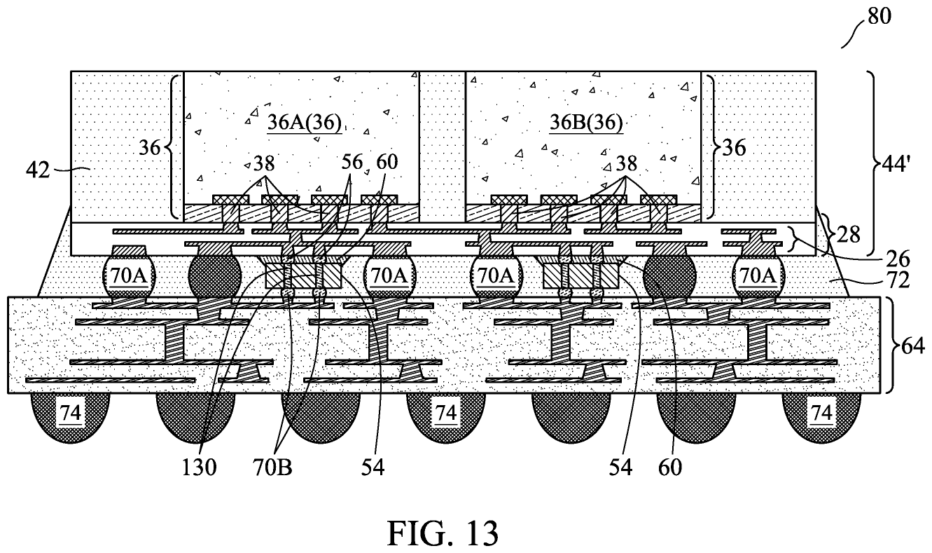

FIG. 13 illustrates package 80 formed using Integrated Fan-out (InFO) process. The formation process may include placing package components 36A and 36B on a carrier (not shown), encapsulating package components 36 in encapsulant 42, and planarizing encapsulant 42 to reveal the electrical connectors 38 in package components 36. Fan-out interposer 28 (also referred to as interposer 28) is then formed layer-by-layer on package components 36 and encapsulant 42. The following processes in accordance with these embodiments are similar to what are shown in FIGS. 7 through 11, and are not repeated herein.

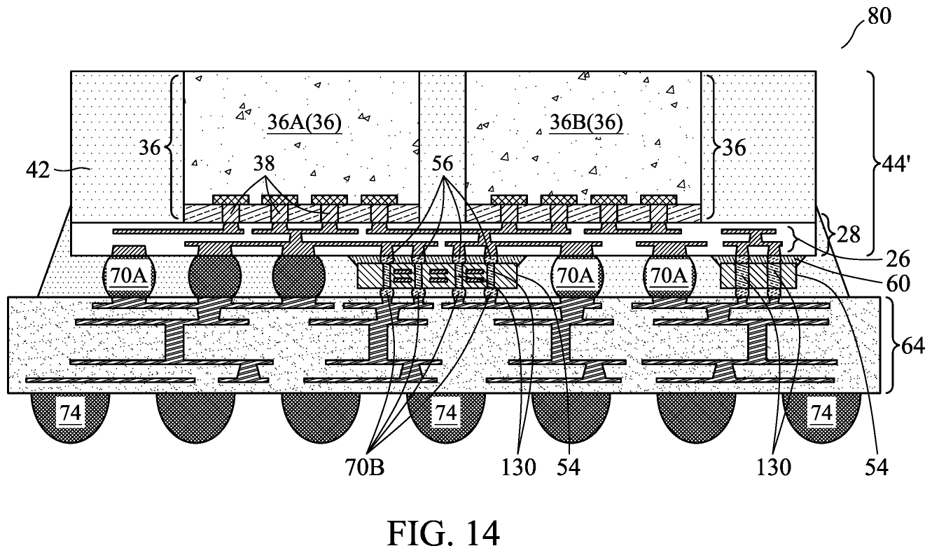

FIG. 14 illustrates package 80, in which IPD 54 is also a bridge die in addition to its other functions, as aforementioned, such as including intelligent power devices and/or passive devices. The formation of package 44′ also adopts InFO processes, similar to what have been discussed referring to FIG. 13.

FIG. 15 illustrates package 80, in which metal posts 82 are formed. Since the lateral sizes of metal posts 82 are fixed (unlike solder regions), solder regions 70A may be formed smaller, and the possibility of bridging is reduced. On the other hand, the formation of metal posts 82 causes the increase in the standoff distance between interposer 28 and package component 64. This is compensated for by etching the top surface dielectric layer(s) 77 in package component 64. Accordingly, solder region 70A extend into the corresponding openings 86 in package component 64. In accordance with some embodiments, the interface between metal posts 82 and the corresponding underlying solder regions 70B may be higher than, at the same level as, or lower than, the top surface of top surface 77T of dielectric layer 77. In accordance with some embodiments of the present disclosure, underfill 72 may extend into the openings 86 in dielectric layer 77 to contact solder regions 70B.

The IPDs 54 in FIG. 15 may also be used as bridging devices. For example, electrical path 126 is schematically illustrated to show that IPD 54 may be used to bridge package components 36A and 36B.

FIG. 16 illustrates package 80, in which IPDs 54 are thick, and the standoff distance between interposer 28 and package component 64 is not enough to accommodate IPDs 54. The surface dielectric layer(s) 77 in package component 64 are thus etched to form openings 86′, so that solder region 70B extend into openings 86′ in package component 64. IPDs 54 may or may not extend into openings 86′. In accordance with some embodiments, the interface between IPD 54 and the corresponding underlying solder regions 70B may be higher than, at the same level as, or lower than, the top surface 77T of top surface dielectric layer 77. In accordance with some embodiments of the present disclosure, underfill 72 may extend into the openings 86′ in dielectric layer 77 to contact solder regions 70B.

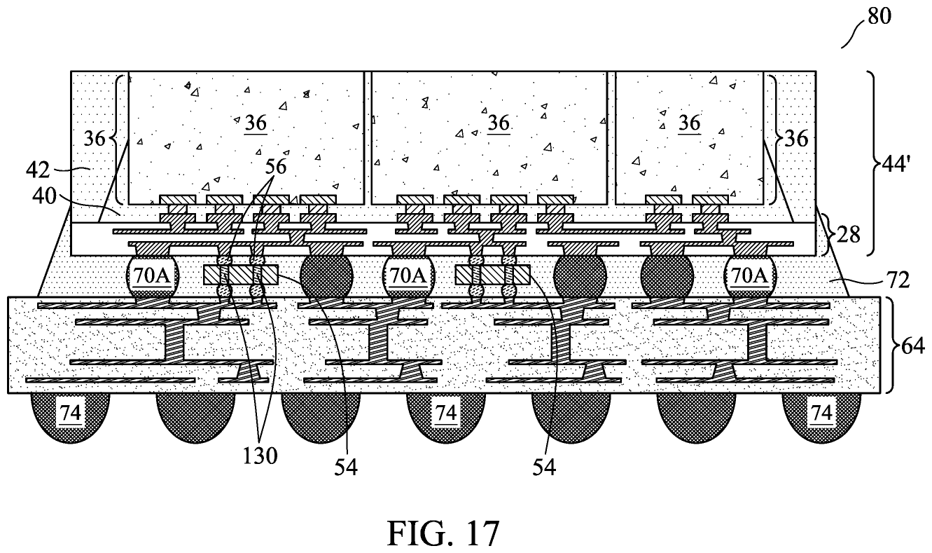

FIG. 17 illustrates package 80 in accordance with some embodiments. These embodiments are similar to the embodiments as shown in FIG. 11, except that the underfills 60 (FIG. 11), which are between IPDs 54 and interposer 28, are not formed in the package 80 shown in FIG. 17.

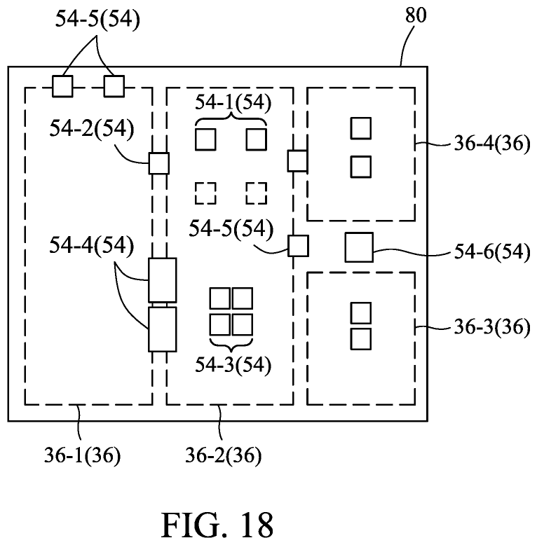

FIG. 18 illustrates a top view of package 80 in accordance with some embodiments. Four example package components 36 (including package components 36-1, 36-2, 36-3, and 36-4) are illustrated. Example IPDs 54-1, 54-2, 54-3, 54-4, 54-5, and 54-6 are also shown. IPDs 54-1 and 54-3 are directly underlying and fully overlapped by package component 36-2. The spacing between neighboring IPDs 54-1 may be greater than the spacings between neighboring IPDs 54-3. IPD 54-2 is overlapped by both of package components 36-1 and 36-2, and does not have other IPDs 54-2 close by. Two IPDs 54-4 are overlapped by both of package components 36-1 and 36-2, and are spaced closely from each other. IPDs 54-2 and 54-4 may be used as bridge dies. IPDs 54-5 are overlapped partially by a single package component 36-1 or 36-2. IPD 54-6 is not overlapped by any package component 36.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. The IPDs in accordance with the embodiments include through-vias, and hence the solder regions on the IPDs have the same function as other solder regions that directly connect the interposer to the corresponding package component. Accordingly, the total count of the solder regions is preserved, and may also be increased compared to the IPDs are not formed. Also, by adopting different bump pitches, the design of the packages is flexible. Metal pillars and/or cavities may be formed to tune standoff distance. The reliability of the package is thus improved.

In accordance with some embodiments of the present disclosure, a method includes forming a first package component comprising an interposer; and a first die bonded to a first side of the interposer; bonding a second die to a second side of the interposer, wherein the second die comprises a substrate; and a through-via penetrating through the substrate; and bonding a second package component to the first package component through a first plurality of solder regions, wherein the first package component is further electrically connected to the second package component through the through-via in the second die, and wherein the second die is further bonded to the second package component through a second plurality of solder regions.

In an embodiment, the method further comprises etching the second package component to form a plurality of recesses, wherein the first plurality of solder regions extend into the plurality of recesses. In an embodiment, the method further comprises forming a plurality of protruding metal posts on the interposer, wherein the first plurality of solder regions join the plurality of protruding metal posts to the second package component. In an embodiment, the plurality of protruding metal posts further extend into the plurality of recesses. In an embodiment, the method further comprises dispensing an underfill between the interposer and the second package component, wherein the underfill extends into the plurality of recesses.

In an embodiment, the method further comprises etching the second package component to form a recess, wherein the second plurality of solder regions extend into the recess. In an embodiment, a part of the second die further extends into the recess. In an embodiment, the method further comprises dispensing an underfill between the interposer and the second package component, wherein the underfill extends into the recess. In an embodiment, the second die is an intelligent power device die. In an embodiment, the second die is a bridge die.

In an embodiment, the first package component further comprises a third die bonding to the first side of the interposer, wherein the second die electrically connects the first die to the third die. In an embodiment, the method further comprises forming the first package component comprising bonding the first die to the interposer. In an embodiment, the method further comprises forming the first package component comprising encapsulating the first die in an encapsulant; and forming the interposer starting from the first die that has been encapsulated in the encapsulant, wherein the interposer is formed using a fan-out process.

In accordance with some embodiments of the present disclosure, a package comprises an interposer; a first device die over and bonding to the interposer; a die underlying and bonding to the interposer, wherein the die comprises a semiconductor substrate; and through-vias penetrating through the semiconductor substrate; a package substrate underlying the die and the interposer; a first plurality of solder regions bonding the interposer to the package substrate; and a second plurality of solder regions bonding the die to the package substrate, wherein the through-vias and the second plurality of solder regions electrically connect the interposer to the package substrate. In an embodiment, the first plurality of solder regions extend into a plurality of recesses in the package substrate. In an embodiment, the interposer comprises a plurality of protruding metal posts that protrude toward the package substrate, and wherein the first plurality of solder regions join the plurality of protruding metal posts to the package substrate. In an embodiment, the second plurality of solder regions and a lower portion of the die extend into a recess in the package substrate.

In accordance with some embodiments of the present disclosure, a package comprises an interposer; a first device die and a second device die over and bonding to the interposer; a die underlying and bonding to the interposer, wherein the die comprises a component selected from the group consisting of an intelligent power device, a passive device, a bridge electrically interconnecting the first device die to the second device die, and combinations thereof, wherein the component comprises a semiconductor substrate, and a through-via penetrating through the semiconductor substrate; and a package component underlying and bonding to both of the die and the interposer, wherein the interposer is electrically connected to the package component through the die. In an embodiment, the package further comprises a first underfill between the die and the interposer; and a second underfill between the interposer and the package component, wherein the first underfill and the die are in the second underfill. In an embodiment, the interposer further comprises a metal post extending to at least a surface of the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first package component comprising:
an interposer; and
a first die bonded to a first side of the interposer;
bonding a second die to a second side of the interposer, wherein the second die comprises:
a substrate; and
a through-via penetrating through the substrate; and
bonding a second package component to the first package component through a first plurality of solder regions, wherein the first package component is further electrically connected to the second package component through the through-via in the second die, and wherein the second die is further bonded to the second package component through a second plurality of solder regions.

2. The method of claim 1 further comprising:
etching the second package component to form a plurality of recesses, wherein the first plurality of solder regions extend into the plurality of recesses.

3. The method of claim 2 further comprising:
forming a plurality of protruding metal posts on the interposer, wherein the first plurality of solder regions join the plurality of protruding metal posts to the second package component.

4. The method of claim 3, wherein the plurality of protruding metal posts further extend into the plurality of recesses.

5. The method of claim 2 further comprising dispensing an underfill between the interposer and the second package component, wherein the underfill extends into the plurality of recesses.

6. The method of claim 1 further comprising:
etching the second package component to form a recess, wherein the second plurality of solder regions extend into the recess.

7. The method of claim 6, wherein a part of the second die further extends into the recess.

8. The method of claim 6 further comprising dispensing an underfill between the interposer and the second package component, wherein the underfill extends into the recess.

9. The method of claim 1, wherein the second die is an intelligent power device die.

10. The method of claim 1, wherein the second die is a bridge die.

11. The method of claim 10, wherein the first package component further comprises a third die bonding to the first side of the interposer, wherein the second die electrically connects the first die to the third die.

12. The method of claim 1 further comprising forming the first package component comprising:
bonding the first die to the interposer.

13. The method of claim 1 further comprising forming the first package component comprising:
encapsulating the first die in an encapsulant; and
forming the interposer starting from the first die that has been encapsulated in the encapsulant, wherein the interposer is formed using a fan-out process.

14. A package comprising:
an interposer;
a first device die over and bonding to the interposer;
a die underlying and bonding to the interposer, wherein the die comprises:
a semiconductor substrate; and
through-vias penetrating through the semiconductor substrate;
a package substrate underlying the die and the interposer;
a first plurality of solder regions bonding the interposer to the package substrate; and
a second plurality of solder regions bonding the die to the package substrate, wherein the through-vias and the second plurality of solder regions electrically connect the interposer to the package substrate.

15. The package of claim 14, wherein the first plurality of solder regions extend into a plurality of recesses in the package substrate.

16. The package of claim 15, wherein the interposer comprises a plurality of protruding metal posts that protrude toward the package substrate, and wherein the first plurality of solder regions join the plurality of protruding metal posts to the package substrate.

17. The package of claim 14, wherein the second plurality of solder regions and a lower portion of the die extend into a recess in the package substrate.

18. A package comprising:
an interposer;
a first device die and a second device die over and bonding to the interposer;
a die underlying and bonding to the interposer, wherein the die comprises:
a component selected from the group consisting of an intelligent power device, a passive device, a bridge electrically interconnecting the first device die to the second device die, and combinations thereof, wherein the component comprises:
a semiconductor substrate; and
a through-via penetrating through the semiconductor substrate; and
a package component underlying and bonding to both of the die and the interposer, wherein the interposer is electrically connected to the package component through the die.

19. The package of claim 18 further comprising:
a first underfill between the die and the interposer; and
a second underfill between the interposer and the package component, wherein the first underfill and the die are in the second underfill.

20. The package of claim 18, wherein the interposer further comprises a metal post extending to at least a surface of the package component.
